(19) United States
(12) Patent Application Publication
(10) Pub. No.: US 2018/0301980 A1
(43) Pub. Date: Oct. 18, 2018

(54) POWER MANAGEMENT UTILIZING A BLOCKER STAGE

(71) Applicant: Resilient Power Systems, LLC, Georgetown, TX (US)

(72) Inventors: Lyle Thomas Keister, Georgetown, TX (US); Joshua David Keister, Georgetown, TX (US); Bradley John Schafer, Fayetteville, GA (US)

(21) Appl. No.: 15/486,992

(22) Filed: Apr. 13, 2017

(51) Int. Cl. H02M 1/32; H02M 7/44; H02M 7/68; G01R 21/06

(52) U.S. Cl. CPC H02M 1/32; G01R 21/06; H02M 7/68; H02M 7/44

(57) ABSTRACT

The present disclosure relates to power management apparatuses, systems, and methods utilizing a blocker stage. A power management apparatus may include a blocking string including a plurality of blocker stages connected in series, and each blocker stage may include at least one switch and at least one energy absorbing component. The apparatus may include a voltage/current monitor configured to monitor a power flow and generate current feedback and voltage feedback. The apparatus may further include a central controller coupled to the voltage/current monitor and configured to switch the energy absorbing components into or out of the power flow by synchronously turning the at least one switch of each of the plurality of blocker stages on or off based on the current feedback and the voltage feedback, where the plurality of blocker stages effectively act as a single blocking component.

### BACKGROUND

The energy industry has been shifting investment to develop new cheaper and cleaner energy sources not related to fossil fuels. Renewable energy resources have been the focus for researchers, and many different power converters utilizing these energy resources have been designed to integrate these types of systems into a distribution power grid. As the power grid evolves, there will be more distributed power sources that are configured into microgrids. Microgrids operate with both utility (power network) and renewable power sources (solar, wind, battery, and/or other) with numerous various loads (single and three-phase). Medium, high, and extra high voltage electronic systems are needed to manage and control power flow, as well as to assure power distribution quality in transmission lines including applications for reactive power (“VAR”) compensators, voltage/frequency regulators, solid-state transformers (“SST”), solid-state power substations (“SSPS”), medium and high voltage direct current (“MVDC”/“HVDC”) converters, medium voltage alternate current drives (“MVD”), and the like. Therefore, power electronic converters with these capabilities have the responsibility to carry out these tasks with high resiliency and efficiency. The increase in the world energy demands has necessitated new power converter topologies and new semiconductor technology.

Traditionally, utilities avoid power electronic products due to cost, complexity, and lack of resiliency. These products require high current components to withstand high current surges produced by transient voltage events and faults. Often power electronic products require expensive external circuit breakers, isolation transformers, contactors, resistors, reactors, filters, arrestors, etc., for additional protection that require additional servicing and maintenance. In addition, these power electronic products require added cost for installation because they are designed for operating in clean controlled environments.

Transient suppressors are required to withstand high current surges produced by transient voltage events. There are two major categories of transient suppressors: those that attenuate transients, thus preventing their propagation into the sensitive circuit; and those that divert transients away from sensitive loads and thus limit the residual voltages. Attenuating a transient, that is, keeping it from propagating away from its source or keeping it from impinging on a sensitive load, is accomplished with filters inserted in series with a circuit. The filter, generally a low-pass configuration, attenuates the transient (high frequency), and allows the signal or power (low-frequency) to continue undisturbed.

The frequency components of a transient may be several orders of magnitude above the power frequency of an alternating current (“AC”) or direct current (“DC”) circuit. Therefore, a typical solution is to install a low-pass filter between the source of transients and the sensitive load. The simplest form of a filter is a capacitor placed across the power line. The impedance of the capacitor forms a voltage divider with the source impedance, resulting in attenuation of the transient at high frequencies. This simple approach may have undesirable side effects, however, including unwanted resonance with inductive components located elsewhere in the circuit leading to high peak voltages, high inrush currents during switching, and/or excessive reactive load on the power system voltage. These undesirable effects can be reduced by adding series resistors. However, the price of the added resistance may be less effective clamping.

Beyond the simple resistor-capacitor (“RC”) network, conventional filters comprising inductances and capacitors are widely used for interference protection. Additionally, they offer an effective transient protection, provided that the filter's frontend components can withstand the high voltage associated with the transient. However, there is a fundamental limitation in the use of capacitors and filters for transient protection when the source of transients in unknown. The capacitor response is nonlinear with frequency, but it is still a linear function of current. To design a protection scheme against random transients, it is often necessary to make an assumption about the characteristics of the impinging transient. If an error in the source impedance or in the open-circuit voltage is made in that assumption, the consequences for a linear suppressor and a nonlinear suppressor are dramatically different.

In normal industry practice, transient protection relies on clamping the random transient voltage to a “known” peak value (“V₁”) through a voltage clamping and energy absorbing component, e.g., an arrestor. Typically, a minimum “known” amount of impedance is placed between the transient source and the electronic circuit. Usually an inductor (“L”) is used because its impedance increases proportionally with frequency. The higher the value of L, the lower the current surge rate of change, but higher impedance effects the power capacity, efficiency, and time response. In combination with L, various low-pass filters may be used to suppress high frequency transients.

During a transient event, the power flow controller's effective input impedance is dominated by its input capacitance and the available current produced by the transient event can be determined by the following equation:

ΔV=L*(Δi÷Δt) or ΔI=(ΔV*Δt)÷L

where ΔV=V₁−Vₚ, V₁=network voltage+transient voltage, and Vₚ=Power flow controller voltage. The transient voltage creates a current (Δi) into the capacitor during the transient event (At). As the current flows into the capacitor, the voltage increases. If semiconductors are in series with the current surge, the component ratings must accommodate the higher current (current surge+normal current during operation). Usually surge current is much higher than normal current, and this may cause existing power flow controllers use higher current devices. Standard commercial inverter products are designed to operate over ±10% input voltage ranges. Some standard commercial inverter products have wider ranges for short periods of time, for instance ±15%, while even others have built-in ride-through options that permit operation at lower levels. These products generally operate without concern of transient events (e.g., direct lightning strikes), and depend on other external components to limit transient energy. These transient events are normal and occur on a daily basis. If a transient event exceeds expectations, the unit may stop operating (e.g., “trip off”) due to an internal fault event, and can require the system operator to clear the fault and resume operation—which is undesirable.

Utility products need to withstand lightning strikes and operate properly when exposed to raw (daily occurring) transients. Utility inverter products need to continue operating with wide fluctuations in voltage. Standards for grid components have evolved that require withstanding as much as four times rated “line to ground” voltage and two times rated “line to line” voltage for time durations of several seconds extending to 60 minutes.

All distribution Class I and Class II transformers (per Institute of Electrical and Electronics Engineers (“IEEE”) Standard (“Std”) C57.12) must withstand induced (no load) voltage as high as two times rated voltage for two minutes, 1.58 times rated voltage for one hour, and withstand 1.5 times rated voltage as an applied voltage to ground. Circuit breakers (per IEEE Std C37.06) must withstand voltage on its terminals open and one side grounded of four times rated voltage for one minute, and in the closed position with same voltage applied between terminals and case/ground. Capacitors (per IEEE Std 18) must withstand two times rated voltage for ten seconds.

Poor power quality problems are experienced daily with the grid networks. These poor power quality problems cause current surges that can harm the network as well as cause instability problems. Passive components, particularly transformers, inductors, capacitor banks, and the like, require high inrush current to magnetize and charge them when power is energized or when line dips and line surges occur. The high inrush current eventually lowers the lifetime of system components including switches, fuses, breakers, and infrastructure. One known method of lowering current surges to capacitor banks is to use thyristors, and control them as zero voltage controlled switches to minimize current during energizing the capacitor banks. However, thyristors turn off slowly and are not very effective to lower current surges during transient voltage events. Another known way to minimize current surges is to temporarily insert series resistance into the circuit before energizing. The additional circuitry is expensive and is a reliability concern because it is difficult to protect. Furthermore, the additional circuitry, like thyristors, do not have a sufficiently fast response time to minimize current surges during transient voltage events.

Moreover, components connected to an AC medium or high voltage network require short circuit protection and a visible means of disconnecting power during service. Due to the high inrush requirements of these components, often an expensive circuit breaker with a visible means of disconnect is used (e.g., rack in or out modular assembly) to protect these components because it can be programmed to ignore inrush currents, whereas a fuse has less tolerance. In situations where a fuse could be used, an integrated visible disconnect switch is required so that safe service can be performed. Some components and equipment continue to require current, even when they are not operating, and may require the disconnect switch to be rated to open under a specific load. For DC applications, medium and high voltage high power DC rated circuit breakers and switches are very expensive and large.

It is with respect to these and other considerations that the disclosure made herein is presented.

### SUMMARY

It is to be understood that this summary is not an extensive overview of the disclosure. This summary is exemplary and not restrictive, and it is intended to neither identify key or critical elements of the disclosure nor delineate the scope thereof. The sole purpose of this summary is to explain and exemplify certain concepts of the disclosure as an introduction to the following complete and extensive detailed description.

The present disclosure relates to controlling power flow utilizing a plurality of blocker stages. According to some aspects, a power management apparatus may comprise a blocking string comprising a plurality of blocker stages connected in series. Each blocker stage may comprise at least one switch and at least one energy absorbing component. The power management apparatus may further comprise a voltage/current monitor configured to monitor a power flow in the power management apparatus and to generate current feedback and voltage feedback. The power management apparatus may further comprise a central controller coupled to the voltage/current monitor, the central controller configured to switch the energy absorbing components of the plurality of blocker stages into or out of the power flow by synchronously turning the at least one switch of each of the plurality of blocker stages on or off based on the current feedback and the voltage feedback. The turning of the at least one switch of each of the plurality of blocker stages on or off synchronously may cause the plurality of blocker stages to effectively act as a single blocking component.

According to further aspects, a power management system may comprise a plurality of ports and a blocking string electrically connected to each of the plurality of ports. Each blocking string may comprise a plurality of blocker stages connected in series. Each blocker stage may comprise at least one switch and an energy absorbing component. Each blocker stage may be configured to switch the energy absorbing component into and out of a power flow from a respective one of the plurality of ports based on a control signal. The control signal may synchronously turn the at least one switch of each of the plurality of blocker stages on or off such that the blocking strings effectively act as a single blocking component. The power management system may further comprise a plurality of inverters, where each inverter may be connected in series with at least one blocking string.

According to further aspects, a method for controlling power flow in a power management system comprises sensing, by a voltage/current monitor, current feedback and voltage feedback. The method further comprises determining, by a central controller, if a transient event has occurred based on the current feedback and the voltage feedback compared to predetermined criteria. Upon determining the transient event has occurred, the method may further comprise synchronously activating a plurality of blocker stages connected in series. Each blocker stage may comprise at least one high speed switch and at least one energy absorbing component. Activating a blocker stage may comprise switching the at least one energy absorbing component into the power flow utilizing the respective at least one high speed switch. Synchronously activating the plurality of blocker stages may effectively act as a single blocking component.

These and other features and aspects of the various aspects will become apparent upon reading the following Detailed Description and reviewing the accompanying drawings. Furthermore, other examples are described in the present disclosure. It should be understood that the features of the disclosed examples can be combined in various combinations. It should also be understood that certain features can be omitted while other features can be added.

### BRIEF DESCRIPTION OF THE DRAWINGS

In the following Detailed Description, references are made to the accompanying drawings that form a part hereof, and that show, by way of illustration, specific aspects or examples. Any illustrated connection pathways in block and/or circuit diagrams are provided for purposes of illustration and not of limitation, and some components and/or interconnections may be omitted for purposes of clarity. The drawings herein are not drawn to scale. Like numerals represent like elements throughout the several figures.

FIG. 1 depicts a block diagram illustrating a power conversion circuit with multi-level blocker stages, according to aspects of the present disclosure.

FIG. 2A depicts a block diagram illustrating a blocker stage assembly including a blocker stage configured as a Bi-Transistor Stage (“BTS”) circuit without a controller, according to various aspects of the present disclosure.

FIG. 2B depicts a block diagram illustrating a blocker stage assembly including a blocker stage configured as a BTS circuit with a controller, according to various aspects of the present disclosure.

FIG. 2C depicts a block diagram illustrating a blocker stage assembly including a blocker stage configured as a Uni-Transistor Stage (“UTS”) circuit with a controller, according to various aspects of the present disclosure.

FIG. 2D depicts a block diagram illustrating a blocker stage assembly including a blocker stage configured with multiple switches with an energy absorbing component in parallel with each switch.

FIG. 3 depicts a block diagram illustrating a blocking string circuit comprising a string of blocker stages connected in series, according to aspects of the present disclosure.

FIG. 4 depicts a block diagram illustrating a three-phase multi-level Cascaded H-Bridge (“CHB”) converter system with blocker stages, according to aspects of the present disclosure.

FIG. 5 depicts a block diagram illustrating a multi-level and multi-port cascaded power management system with synchronous common coupling utilizing a 3-port cell with blocker stages, according to various aspects of the present disclosure.

### DETAILED DESCRIPTION

The aspects described herein are directed to high-frequency power electronics, more particularly to utilizing one or more fast electronic switches to switch in/out of an energy absorbing component to suppress and avoid transients. Utilizing the apparatus' described herein, the use of one or more strings, which are one or more fast electronic switches connected in series, may increase the blocking and voltage-withstanding of the power circuit and be more effective without increasing current and voltage ratings of the sensitive circuit, thus reducing cost by reducing the need for expensive components to withstand high current surges produced by transient voltage events.

According to aspects described herein, a blocker stage utilizes one or more fast (e.g. turns on or off within microseconds) AC/DC electronic switches, which may be utilized to reduce DC current flow to less than a few milliamps, even during faults, to enable using less expensive and smaller circuit breakers and switches. For example, the switch or switches within a blocker stage may be switched on (in less than 10 microseconds) and off. This is an advantage in power electronic AC and/or DC solid-state transformer (“SST”) applications because when SST ports are paralleled together to increase power flow, each port has a blocker in series with a string of inverters. If an internal fault occurs in one of the parallel strings, the blocker in that string can open without interrupting the parallel string(s). This also enables each port/string to have a low cost disconnect switch means to “hot swap” the faulted assembly without removing power from the rest of the system. In some aspects, each port can have independent electronic switches and the normal operating current of one port can be a fraction of the total current flow.

The aspects described herein may provide significant advantages when used in state of the art electromechanical and power electronics used in power conversion products across a variety of applications, such as VAR compensation, power factor correction, voltage and frequency regulation, solid-state transformers, solid-state power substations, medium voltage AC drives, medium and high voltage DC converters, test stands, and others, by utilizing one or more scalable bi-directional AC/DC blocker stages in series with an inverter within a medium and a high voltage power management system.

According to aspects described herein, the change in voltage in an example power conversion system may be represented by the equation:

ΔV=V₁−Vₚ₁

Where V₁ is equal to the network voltage plus transient voltage condition, and Vₚ₁=voltage capability of a number of series inverter stages. As a transient event occurs, a power flow controller uses voltage and/or current feedback to determine what action to take. The feedback signal may be filtered in an analog circuit and/or a digital circuit. The voltage (V₁) and/or current (I) are continuously monitored. When a transient event occurs, (V₁) and (I) see a change, where I=I_{load}+ΔI.

When the voltage and/or current exceeds a limit for a preset time interval, the blocker stage is changed from a low resistance to a high resistance (Vₚ₃), and the power electronic inverter stages temporarily turn Off (blocking voltage rises from Vₚ₁ to Vₚ₂). These two actions increase overall Vₚ which decreases ΔV across the inductor, which, in turn, decreases ΔI until the transient event is over. This example can be represented by the equation:

ΔV=−Vₚ=−(Vₚ₂+Vₚ₃)

For three-phase AC systems, a power conversion system with implemented blocker stages works in a similar manner except that the electrically floating neutral instantaneously shifts during the transient event to help further reduce ΔV. This further reduces ΔI and enables the blocker stages in other phases to assist with energy absorption as well as instantaneously blocking the transient voltage.

According to some aspects, a blocker stage, or multiple blocker stages connected in series, may be used to lower current surges during transient events. In an exemplary aspect, a cascaded arrangement of blocker stages connected in series is referred to herein generally as a “blocking string.” A blocking string can be used to energize as well as eliminate current flow if the electronic power flow control product is not operating or experiencing an internal fault. Current surges in the network system caused by powering up components or equipment or caused by voltage transients cause considerable component, product, and system cost. A blocking string may be used in addition to existing network arrestors and electronic filters. A blocking string may be especially effective to eliminate the need for over sizing semiconductor current or voltage ratings. Therefore, a blocker stage or a blocking string need not be designed to permit large fault or surge currents as a typical circuit breaker or switch is designed for. A blocking string may deliberately operate to limit the current surge and quickly block voltage while the energy absorbing component in each blocker stage absorbs energy.

According to some aspects, an exemplary blocking stage comprises a fast on/off cascaded AC switch (e.g. a transistor) with a simple control circuit for fast on/off control in the presence of a transient, in order to provide reliability. The blocking stage may further comprise an integrated protective, balanced surge protection utilizing a varistor. The varistor may be designed to normally form a divider for even voltage distribution for cascaded switches during the off mode without any transient present. If a voltage transient is present when there is no power flow to the power management system or product, the varistor may clamp the voltage to a predictable level below the semiconductor breakdown voltage because the series inductor limits the current. In an exemplary power management system with blocking strings comprising of cascaded blocking stages, multiple varistors may be in series during the surge, and the voltage balance is therefore evenly distributed. According to some aspects, the varistor may comprise a resistor, an arrestor, or other energy absorbing components known in the art. When the AC switch is on, the AC switch may provide a low resistance path for power to flow and the varistor would be limited to a minimal amount of voltage across it, providing longevity for the life of the component.

According to some aspects, the power management system may be designed so that the default configuration of the blocker stage is in a “normally off” mode (also referred to herein as “Standby mode”) when no power is supplied by a high speed switching power supply, thus protecting downstream circuitry throughout the power management system during a transient event. According to some aspects, the blocker stages may comprise a simple means to turn on/off during a disturbance. According to some aspects, the blocker stage may act as a normally open blocker stage. According to some aspects, the blocking stage may not galvanically interrupt current, but in the off mode the blocking stage may provide a very high resistance in series with the power management system. According to some aspects, when the blocking stages are in the Standby mode (off mode), the blocking components are switched into the current flow and resists current, and when the blocking stages are in the on mode, the switches provide a low resistance patch to bidirectional current flow.

According to some aspects, the blocker stage may comprise of semiconductor transistor(s) (insulated gate bipolar transistors (“IGBTs”), metal-oxide-semiconductor field-effect transistors (“MOSFETs”), or the like), semiconductor diodes, an arrestor, voltage balancing resistors, and a controller. The blocker stage may be configured as a bi-directional AC/DC power switch configured as a Bi-Transistor Stage (“BTS”), a Uni-Transistor Stage (“UTS”), or other configurations described herein. According to aspects described herein, both types of blocker stage configurations may be normally off when no gate voltage is present and turn on when gate voltage is present.

According to some aspects, the blocker stage may be scalable, such that multiple blocker stages are cascaded in a blocking string, where more than one blocker stage is connected together in series and configured to operate synchronously, acting as one higher voltage blocker stage. Thus, the synchronous switching of the switches of each blocker stage allows the blocking string to collectively act as a single blocking component. In the some aspects, a switch controller may be controlled by a central controller to turn each switch in each blocker stage on or off quickly (e.g., less than 20 microseconds), so each switch can block a large fast transient event including lightning. For lower voltage transient events with normally longer durations including capacitor bank switching, the system can take more time to recognize the transient, however in all cases, once the transient event is recognized, the blocker is turned on quickly (5 to 10 microseconds) and after the transient event has passed, turns off the blocker quickly (5 to 10 microseconds). The system response is dependent on magnitude and duration and this minimizes unnecessary operation. Once a transient is recognized, the blocker stage always reacts quickly to minimize the effects of a wide range of voltage transients. In some aspects, one central controller may control all of the switch controllers to control the switches in each of the plurality of blocker stages which may be comprised in the one or more blocking strings, therefore reducing overall cost to control each switch.

According to some aspects, a blocker stage may operate without a switch controller, and each switch within each blocker stage is turned off or on by the application of power to the blocker stage from a single high speed switching power supply that is controlled by the central controller, therefore reducing overall cost to control each switch since each blocker stage would not require a separate switch controller. Thus, the central controller may detect a transient event and send a control signal to the high speed switching power supply to control the switches. According to some aspects, the high speed switching power supply may synchronously turn each switch in each blocker stage on or off very quickly (e.g., less than 20 microseconds), so each switch can block a large fast transient event including lightning. Thus, the synchronous switching of the switches of each blocker stage allows the blocking string to collectively act as a single blocking component.

According to some aspects, for lower voltage transient events with normally longer durations including capacitor bank switching, the power management system may take more time to recognize the transient, however, once the transient event is recognized, the switches in the plurality of blocker stages are turned on quickly (5 to 10 microseconds) and after the transient event has passed, the central controller may turn off the switches quickly (5 to 10 microseconds). According to some aspects, the power management system response is dependent on magnitude and duration, and this minimizes unnecessary operation.

According to some aspects, if one blocker stage is off and the rest are on, e.g. due to a failure in the control or assembly, in the power up mode in the power flow management, the rest of the blocker stages may be turned off to avoid component failure due to overvoltage (interrupting operation) or the blockers can remain on and permit a controlled open failure of the varistor, which enables semiconductors to form a short circuit bypass around the failed blocker stage (which enables the power management system to continue uninterrupted operation). If the power management system is operating or off, and one blocker stage opened, the power flow management has two options: stop operation to protect the blocker stage, or continue operating letting the varistor fail in short amount of time. If power flow management continues to operate, the varistor may become an open circuit due to overheating, and let the voltage across the AC switch exceed the semiconductor breakdown voltage causing it to short, and thereby allowing the power flow management to continue operation without stopping. This is also known as self-healing. According to some aspects in an exemplary string of blocker stages, a power flow controller has an inductor in series with power flow. The blocking stage may use pulse width modulation (“PWM”) to soft charge the power flow controller to minimize surge currents or use PWM to the off mode to minimize voltage transients from inductive loads.

Utilizing blocker stages may be used to effectively increase voltage capability (Vₚ) to lower or eliminate current flow during transient events, power up, standby operation, or fault events. This lowers product cost by reducing required component ratings.

Utilizing blocker stages may further enable the power electronic product to meet utility requirements to withstand more than two times rated voltage for over one hour, which meets utility rather than commercial requirements. In addition, blocker stages may eliminate surge currents when there is a demand for power electronic products with increasing lifetime of network components and infrastructure.

Blocker stages may quickly and momentarily turn off during transient events to lower current surge, and after the event is over, turn back on. This action may increase network stability and increase overall power quality. According to some aspects described herein, when the blocker stages are in series with power electronics implemented as a transformer or power router, the quickly and momentarily turning off during transient events to lower current surge may prevent transients from being passed along with normal power to the rest of the system, which in turn may increase system stability.

A blocker stage may operate efficiently during normal operation and if the power electronic product is turned off, then the blocker stage may change to a high resistance state as “open,” to reduce current to zero quickly and permit a no load disconnect switch to be used for servicing.

A blocker stage may lower the short circuit current rating requirements because blocker stage can operate quickly and absorb energy during and after a fault clearing event. In addition, according to some aspects, a normally off blocker stage may reduce cost of DC breakers in AC or DC SST type applications by reducing clearing requirements. Further, according to some aspects, a blocker stage may be used for soft charging during power up, controlled to turn on near voltage zero to thyristors to lower inrush, and/or control current to low value by switching on/off quickly until equipment is charged.

In some aspects, multi-level and multi-port cascaded power management systems utilizing blocker stages are used with significant improvement in cost, performance, part count, size, efficiency, and resiliency over existing topologies. In some aspects, synchronous common coupling may be used to link the power flow between multiple electrically isolated and non-isolated AC/DC sources and loads to provide a hub for independent power flow control that is indifferent to voltage magnitude, frequency, and phase. Each power circuit may be provided with a synchronous common coupling to other power circuits to better control power, while maintaining electrical isolation between circuits.

Further, some components used by the aspects described in this disclosure may be implemented with soft switching and rate of voltage change (“DV/DT”) filters along with magnetic and electrostatic shields. Further, some aspects may also be implemented with low parasitic capacitance and inductance to reduce electrical noise interference internally between circuits.

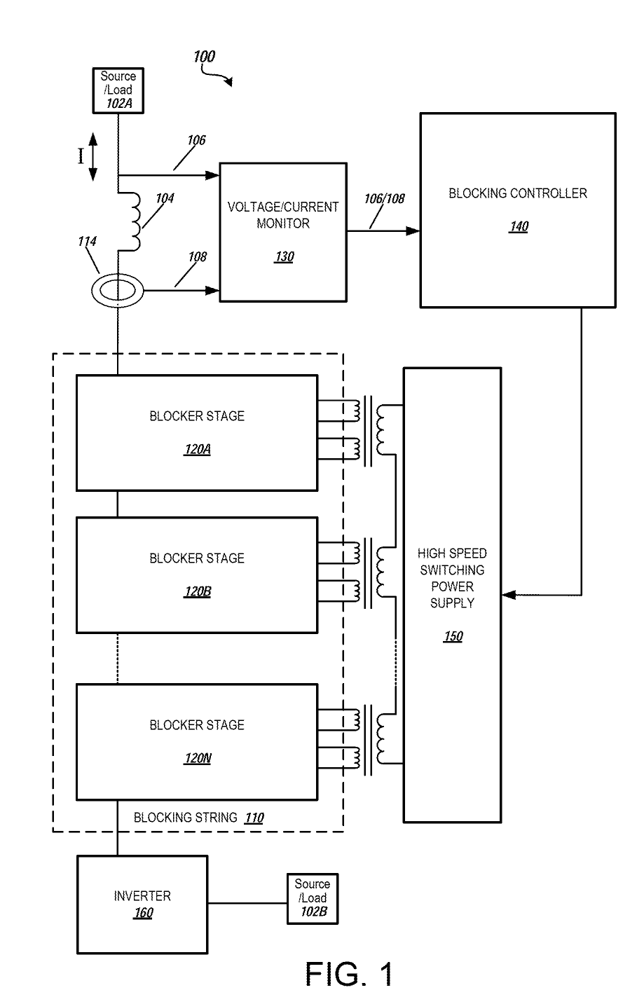

FIG. 1 is a block diagram illustrating a power conversion circuit 100 with multi-level blocker stages, according to some aspects described herein. In the example aspect shown in FIG. 1, the power conversion circuit 100 may be implemented with multiple blocker stages 120A-N (also referred to herein generally as blocker stages 120) connected in series (also referred to herein generally as a blocking string 110), with an inverter 160 connected in series with the last blocker stage 120N. The power conversion circuit 100 may also include a voltage/current monitor 130, a blocking controller 140, and a high speed switching power supply 150. According to some aspects, the inverter 160 may be connected to a source/load 102B to complete the circuit between source/load 102A and source/load 102B for bi-directional power flow. According to some aspects, the high speed switching power supply 150 may connect to the electrically isolated windings of each blocker stage 120, as is further described herein. The inverter 160 may comprise any electronic device or circuitry that changes DC to AC and AC to DC, such as a conventional multi-level cascaded power conversion circuit, a multi-level Cascaded H-Bridge (“CHB”) topology utilizing synchronous common coupling, or the like.

According to some aspects, the power conversion circuit 100 may be bi-directional such that the circuit is indifferent to whether a source or a load connection is connected. In the example aspect shown in FIG. 1, the power conversion circuit 100 may be implemented with a current regulating reactor 104 located between the source/load 102A and the first blocker stage 120A to minimize current harmonics. The current regulating reactor 104 may also provide protection from lightning or large fast network voltage transients.

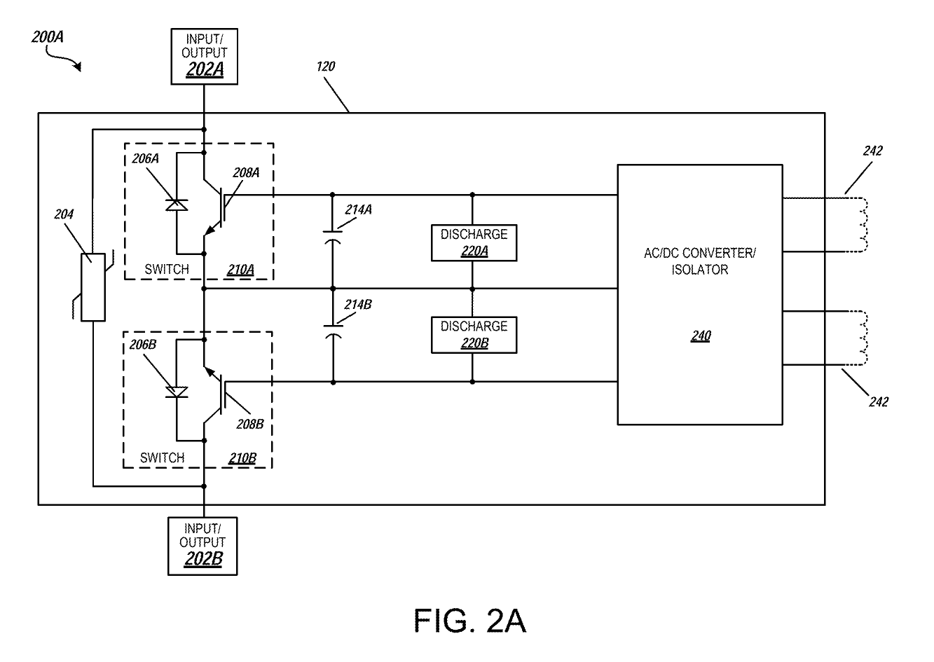

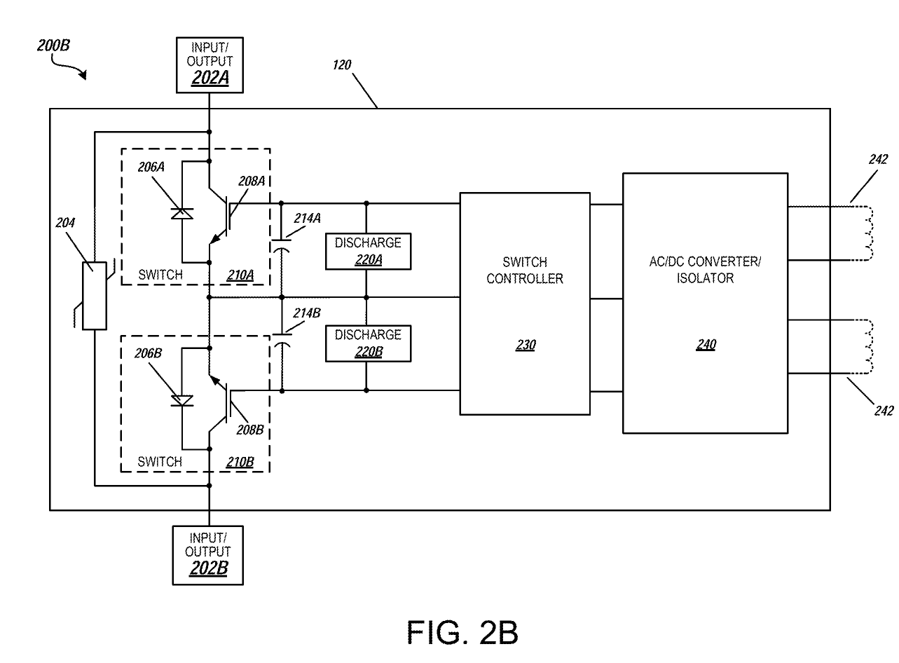

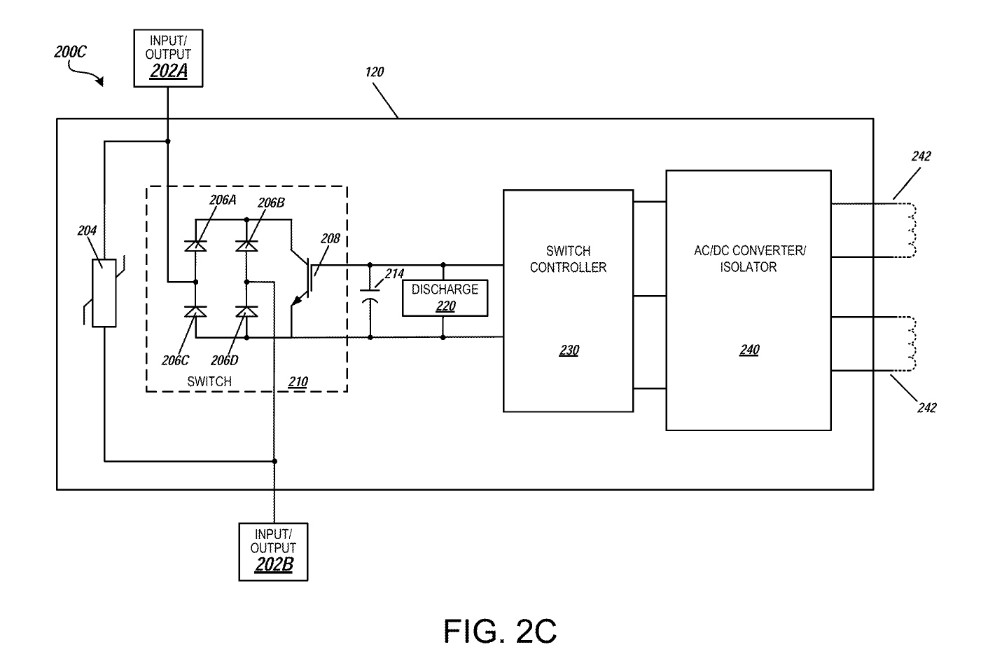

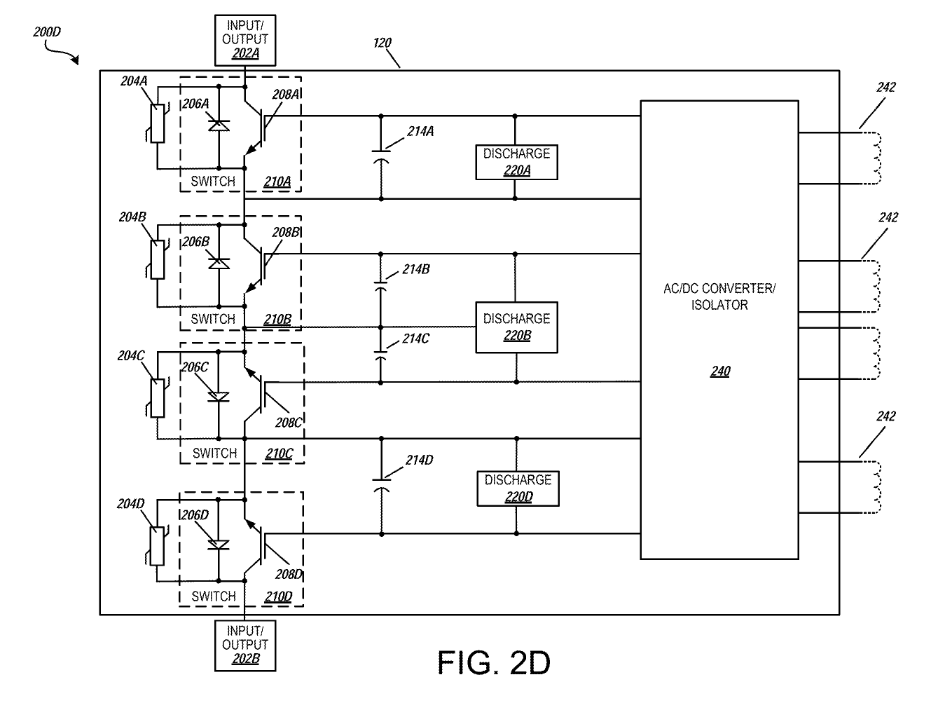

FIGS. 2A-2D are block diagrams illustrating various blocker stage assemblies 200A-200D, according to some aspects described herein. Each blocker stage assembly 200A-D may comprise a connection to an input/output 202A,B, a blocker stage 120, and electrically isolated windings 242. Each blocker stage 120 may comprise an energy absorbing component, such as an arrestor 204, in parallel with a single switching component or multiple switching components, such as switches 210A,B (also referred to herein generally as switches 210). Each blocker stage 120 may further comprise discharge components 220, capacitors 214, and an AC/DC converter/isolator 240. According to some aspects, each switch 210 may comprise a combination of transistors 208 and diodes 206. According to some aspects, each switch 210 may comprise of one transistor 208, or may comprise of several transistors used in parallel to effectively create one transistor.

FIG. 2A depicts a block diagram illustrating a blocker stage assembly 200A including a blocker stage 120 configured as a BTS circuit without a controller. As shown in FIG. 2A, an exemplary blocker stage 120 may comprise an arrestor 204, which is utilized for clamping voltage while diverting the current around the switch(es) 210 of the blocker stage 120, so the power flow does not exceed the transistor(s) 208 or diode(s) 206 respective voltage ratings. In an exemplary aspect as shown in FIG. 2A, an arrestor 204 is utilized so that its energy absorption required during a transient event is within its joule rating, and the arrestor 204 can dissipate steady state losses if the blocker stage 120 is in the off state and voltage is a normal condition. In some aspects, other energy absorbing components known in the art with similar voltage clamping capabilities may be used in lieu of the arrestor 204.

According to some aspects, opening the switches 210 of the blocker stage 120 and utilizing the arrestor 204 immediately reduces the voltage across a port inductor (current regulating reactor 104). The reduced voltage across current regulating reactor 104 slows current rate of rise. The switches 210 may be turned on (low resistance state) by applying a DC voltage to the gate from the AC/DC converter/isolator 240 and turned off (high resistance state) by removing gate voltage from the switch 210. The higher the gate voltage, the lower the conduction losses for each switch 210. A ceramic capacitor 214 may be connected to the switch 210 to aide in preventing electrical noise from causing oscillations. In other aspects, an optional control circuit, such as switch controller 230, may be used to control each switch 210 directly, as further shown herein in FIGS. 2B-2C.

The AC/DC converter/isolator 240 may convert AC voltage from the high speed switching power supply 150 to DC and electrically isolate the blocker stage circuitry from the high speed switching power supply 150 using any number of methods known in the art. According to some aspects, the switches 210 can require high speed switching to minimize DC smoothing capacitance requirements. Additionally, in some aspects, the AC/DC converter/isolator 240 may include very fast rectifiers. The switches 210, ceramic capacitors 214, switch controller 230, AC/DC converter/isolator 240, and windings 242 may be designed so that rise and fall time transitions are fast enough to avoid damaging the switch 210 when it is turning off.

According to some aspects, when the gate voltage (i.e., DC voltage from the AC/DC converter/isolator 240) is removed, a discharge component 220 may be used to remove a charge from the transistor “gate.” In some aspects, the discharge component 220 may be a passive resistor discharge circuit. In other aspects, the discharge component 220 may be an active discharge circuit. A faster discharge rate reduces the time that the switch 210 conducts current with very low control voltages. The discharge component 220 may be implemented in a number of ways known in the art. According to some aspects the discharge component 220 may discharge the gate as soon as the power supply is turned off, which may minimize the time that the gate is required to turn off. In some aspects, the discharge component 220 may provide under voltage detection which may comprise of an RC filter and a gate resistor gate capacitor (“Rg×Cg”) filter, where the RC filter may be faster than the rise and fall time of the Rg×Cg filter.

The lower the gate voltage, the higher the conduction voltage for a given current. As the voltage drops, it reaches the threshold voltage and the switch 210 can no longer operate in saturation (low losses) but pulls out of saturation (“DESAT”). Typically, insulated gate bipolar transistors (“IGBTs”) and metal-oxide-semiconductor field-effect transistors (“MOSFETs”) can survive DESAT for about 10 microseconds; therefore, if the fall time and rise time is much less than 10 microseconds, the switch 210 is not harmed when turned off.

In an exemplary blocker stage 120, a diode 206 may be in anti-parallel with a transistor 208 to comprise a switch 210. When the network frequency is low (e.g. 50-60 Hz, or DC), then the transistor 208 may not suffer high losses if the gate control to each switch 210 is a DC voltage during normal operation. In the off or high resistance state, the arrestor 204 may form a divider with any other arrestors (other BTS or UTS assemblies of blocker stages 120) connected in series within a blocking string 110 and with the blocking voltage of the active stages in the off state (if they are energized). In some aspects, the blocker stage 120 may use additional voltage balancing resistors in parallel with the semiconductors to improve voltage distribution within the assembly, when the blocker stage 120 is off and blocking voltage with the energy absorbing components.

According to some aspects, each blocker stage 120 may have three modes of operation. The first mode is a Standby mode (sometimes referred to herein as “normally off mode”), and control power may not be required. In Standby mode, the arrestor 204 forms a divider and the applied voltage across each arrestor 204 is below its continuous rating. The second mode is an On mode, which comprises the power electronic product as energized and control power to each blocker stage 120 turns on the switches 210. In the On mode, the arrestor 204 may be bypassed and the switches 210 conduct the current. The third mode may comprise a Switching mode for during and after a transient event. In this Switching mode, the arrestor 204 may be inserted during a transient event while the switches 210 are turned off and bypassed when the event is over.

Referring again to FIG. 1, according to aspects described herein, a voltage transient from the source/load 102A is detected by sensing current “I” and/or line to system ground (e.g., system neutral voltage) utilizing the voltage/current monitor 130. The voltage/current monitor 130 may receive the voltage feedback 106 by measuring the voltage on the network side of the current regulating reactor 104 with respect to system ground. The voltage/current monitor 130 may receive the current feedback 108 by measuring the current utilizing a current sensor 114. The voltage and current feedback 106/108 is then sent from the voltage/current monitor 130 to the blocking controller 140. If a predetermined level of a voltage transient is present with both magnitude and duration, the current through the current regulating reactor 104 begins to increase, with the rate depending on the voltage magnitude of the transient event. If the voltage and/or current limits are reached, the blocking controller 140 turns the blocker stages 120 off, which increases the effective product blocking voltage. This action immediately reduces the slope of the rising current. During this time, energy absorbing components within the blocker stages 120, such as varistors or arrestors 204, are switched in parallel with the power flow, and provide an alternate path for the current to flow, and absorb some of the energy produced by the transient event. The blocker stage 120 may deliberately operate to limit the current surge and quickly block voltage while the energy absorbing component in each blocker stage 120 absorbs energy.

According to an exemplary aspect as shown in FIG. 1, a central controller, such as blocking controller 140, may determine if a transient event has occurred based on the current feedback 108 and the voltage feedback 106 sensed by the voltage/current monitor 130 when compared to predetermined criteria. The predetermined criteria may comprise of preset time intervals on when to turn off or on each switch 210 within each blocker stage 120. For example, in the exemplary aspect, each blocker stage 120 is normally off in a Standby mode (e.g., the power management system or product is turned “off”), and each switch 210 is off such that the energy absorbing component (arrestor 204) is in the power flow. The blocker stage 120 may be turned on, where each switch 210 is on and the energy absorbing component (arrestor 204) is out of the power flow when the blocking controller 140 provides the on command (e.g. “On” mode) either via the high speed switching power supply 150 or directly to an optional controller in each blocker stage 120, as further described herein. When in the On mode if a transient has been detected, the blocking controller 140 may control each blocker stage 120 to switch off, which, in turn, switches the energy absorbing component into the power flow.

According to some aspects, to determine whether a transient event has occurred or is currently transpiring, the blocking controller 140 may utilize several preset time intervals to determine when to switch to Off mode and switch the energy absorbing component into the power flow in each blocker stage 120. For example, according to some aspects, if no voltage (with respect to system ground) is present at the source/load 102 for some time interval, then the switches 210 may be turned off, i.e. the arrestor 204 is switched into the power flow of the circuit. According to some aspects, if the measured voltage with respect to system ground, i.e., voltage feedback 106, at the source/load 102 exceeds a voltage threshold for a second time interval, then the switches 210 may be turned off. According to some aspects, if the rate of change in current exceeds a rate threshold for a third time interval, then the switches 210 may be turned off. According to some aspects, if the measured current from the source/load 102 (current feedback 108) exceeds a current threshold for a fourth time interval, then the switches 210 may be turned off.

According to some aspects, the blocking controller 140 may turn all the blocker stages 120 off and switch the energy absorbing component into the power flow effectively by turning off the power to the high speed switching power supply 150. In further aspects, the blocking controller 140 may turn all the blocker stage 120 off directly by sending an “ON/OFF” control signal a controller within each blocking stage (e.g., switch controller 230) for a faster response to turn off each blocker stage 120, as further described herein. An exemplary blocking controller 140 may turn all the blocker stages 120 on when the voltage is greater than the minimum acceptable value, and the current slope and current magnitude are acceptable. In some aspects, there may be a minimum (not less than 5 microseconds) and a maximum (not greater than 500 milliseconds if inverter 160 is operating in On mode) OFF/ON period during operation of the blocking controller 140. If inverter 160 is operating in the Off mode, then there is no maximum OFF period.

Referring again to FIG. 2A, a blocker stage 120 of the blocker stage assembly 200A, configured as a BTS circuit, may comprise two switches 210A,B and an arrestor 204. In the example shown, each switch 210 may comprise a transistor 208 connected with an anti-parallel diode 206. Each diode 206 may comprise an integrated body diode or comprise two discrete diodes. In the example aspect, the parasitic inductance for an AC power flow between input/output 202A and input/output 202B, should be lower for the arrestor 204 circuit than the switch 210 so that the voltage is clamped at a safe level for the semiconductors. Further, the gate drive voltage to each switch 210 may be a DC voltage and may not require synchronizing with the AC line (if AC power is being used).

During operation, the blocker stage 120 of the blocker stage assembly 200A normally operates in a Standby mode, or may operate in the On mode or Switching mode as discussed herein. According to some aspects, as shown in FIG. 2A, for AC power, one half cycle of AC current may flow through transistor 208A and diode 206B, and the other half cycle may flow through transistor 208B and diode 206A. According to some aspects, for DC bi-directional power, power may flow through transistor 208A and diode 206B in one direction, and may flow through transistor 210B and diode 206A in the other direction.

FIG. 2B depicts a block diagram illustrating a blocker stage assembly 200B including a blocker stage 120 configured as a BTS circuit with a switch controller 230. As shown in FIG. 2B, a blocker stage 120 of the blocker stage assembly 200B, configured as a BTS circuit, may comprise the same components as described herein for the blocker stage 120 of the blocker stage assembly 200A. In addition, as shown in FIG. 2B, the blocker stage 120 may comprise a switch controller 230. As described herein, the switch controller 230 may receive an “ON/OFF” signal directly from a blocking controller 140 for a faster response as opposed to utilizing the gate voltage control from the DC power flow from the AC/DC converter/isolator 240 as described herein for FIG. 2A.

FIG. 2C depicts a block diagram illustrating a blocker stage assembly 200C including a blocker stage 120 configured as a UTS circuit with a switch controller 230, according to various aspects of the present disclosure. As shown in FIG. 2C, a blocker stage 120 of the blocker stage assembly 200C may comprise of one switch 210 and an arrestor 204. The switch 210 may comprise of one transistor 208 and four diodes 206A-D.

During operation, the blocker stage 120 of the blocker stage assembly 200C normally operates in a Standby mode, or may operate in the On mode or Switching mode as discussed herein. According to some aspects, as shown in FIG. 2B, for AC power, one half cycle of AC current can flow through transistor 208 and diodes 206A,D, and the other half cycle flows through transistor 208 and diode 206B,C. According to some aspects, for DC bi-directional power, power flows through transistor 208 and diodes 206A,D in one direction and through transistor 208 and diode 206B,C in the other direction.

FIG. 2D depicts a block diagram illustrating a blocker stage assembly 200D including a blocker stage 120 configured with multiple switches 210 with an energy absorbing component in parallel with each switch 210. As shown in FIG. 2D, a blocker stage 120 of the blocker stage assembly 200D, may comprise of four switches 210A-D and four arrestors 204A-D. In the example aspect as shown in FIG. 2D, there are two switches 210 of each polarity connected in series. However, according to some aspects, any number of switches 210 may be used as long as an equal number of each are connected in series in the opposite polarity.

During operation, the blocker stage 120 of the blocker stage assembly 200D normally operates in a Standby mode, or may operate in the On mode or Switching mode as discussed herein. According to some aspects, as shown in FIG. 2D, for AC power, one half cycle of AC current can flow through transistors 208A,B and diodes 206C,D, and the other half cycle flows through transistors 208C,D and diodes 206A,B. According to some aspects, for DC bi-directional power, power flows through transistors 208A,B and diodes 206C,D in one direction and through transistors 208C,D and diodes 206A,B in the other direction.

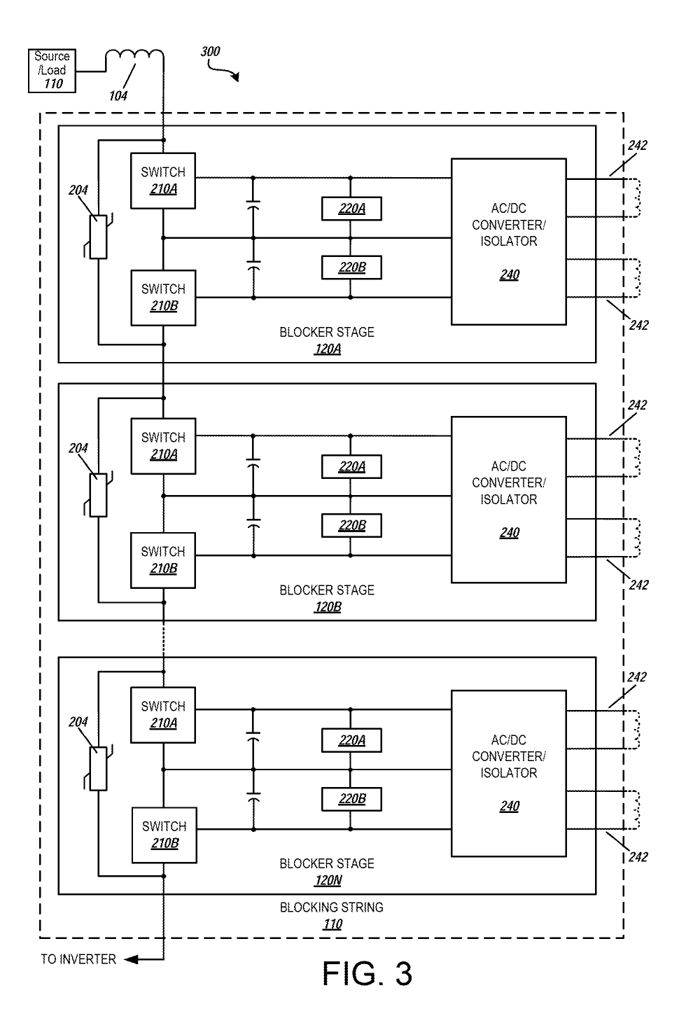

FIG. 3 is a block diagram illustrating a blocking string circuit 300 comprising a blocking string 110 of one or more blocker stages 120A-N connected in series, according to some aspects described herein. As shown in FIG. 3, an exemplary blocking string circuit 300 may comprise a source/load 102 connected to a first blocker stage 120A of the blocking string 110, and a last blocker stage 120N of the blocking string 110 connected to an inverter. According to some aspects, the blocking string circuit 300 may be implemented with a current regulating reactor 104. According to some aspects, the number of blocker stages 120 used in the blocking string 110 is scalable depending on the voltage requirements of the blocking string 110 used in a power management apparatus/system or a power conversion apparatus/system. As described herein, each blocker stage 120 of a blocking string 110 may be controlled by a central controller, such as blocking controller 140, and powered by a switching power supply, such as high speed switching power supply 150.

As shown in FIG. 3, each blocker stage 120 may not have an optional control, such as switch controller 230, for a blocking controller 140 to control directly; therefore, each switch 210 within each blocker stage 120 is controlled by a blocking controller 140 by regulating the high speed switching power supply 150, according to methods described herein. Optionally, each blocker stage 120 may comprise a respective switch controller 230 for direct control over each switch 210 in each blocker stage 120.

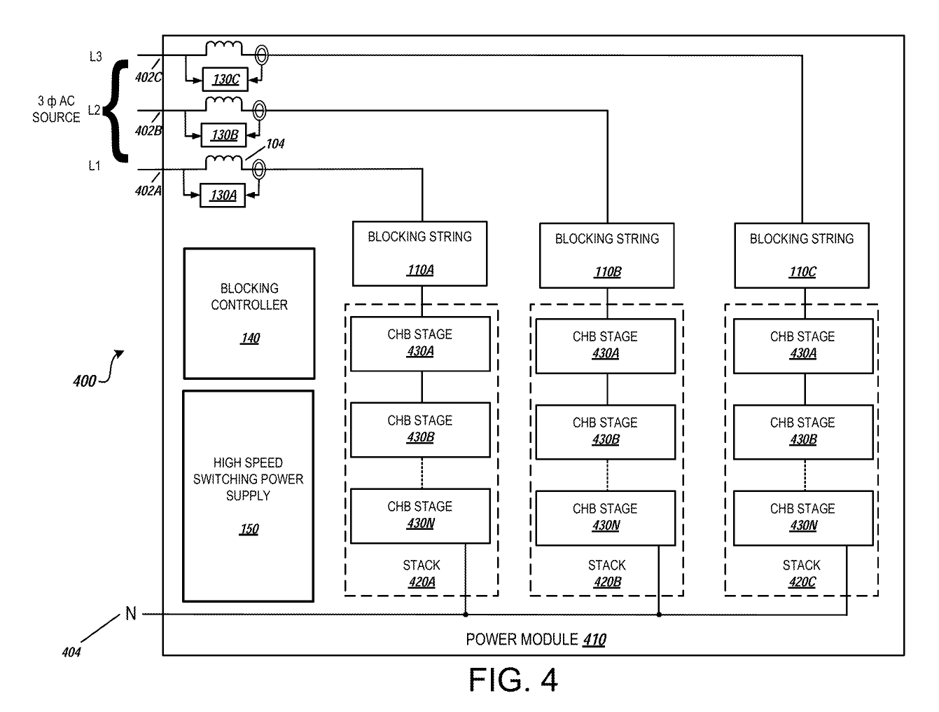

FIG. 4 is a block diagram illustrating a three-phase multi-level CHB converter system 400 in a shunt application used for VAR compensation and line balancing, according to some aspects described herein. According to some aspects, the three-phase multi-level CHB converter system 400 may be implemented with a 3-port system comprising a power module 410 comprising three power module ports 402A-C connected to each line of a three-phase source. As shown in FIG. 4, the power module 410 may be implemented with a current regulating reactor 104, a voltage/current monitor 130, a blocking string 110, and a stack 420 of CHB stages for each power line of the three-phase source. Further, the power module 410 may be implemented with a blocking controller 140 and a high speed switching power supply 150 to control and activate each switch 210 within each blocker stage 120 contained within the power module 410. As discussed herein, a blocking string 110 may comprise one or more blocker stages 120 connected in series. As shown in FIG. 4, each stack 420 may comprise one or more cascaded CHB stages 430A-N. Further, in the example aspect, the last CHB stage 430N of each stack 420 is connected to a neutral electrical connection, or “neutral” 404. The neutral 404 may be electrically floated and/or grounded by means of a solid conductor or one or more external network components such as a resistor, an inductor, or a capacitor. In some aspects, the three-phase multi-level CHB converter system 400 may comprise an enclosure with grounding provisions.

According to some aspects, two or more power modules 410 may be connected in parallel, and each respective power module 410 would provide a respective blocking controller 140 and a respective high speed switching power supply 150 to control and activate each blocker stage 120 contained within the respective power module 410. However, in other aspects with two or more power modules 410 connected in parallel, each power module 410 could utilize the same blocking controller 140 and/or high speed switching power supply 150 to control and activate every blocker stage 120 contained within all of the power modules 410 connected in parallel.

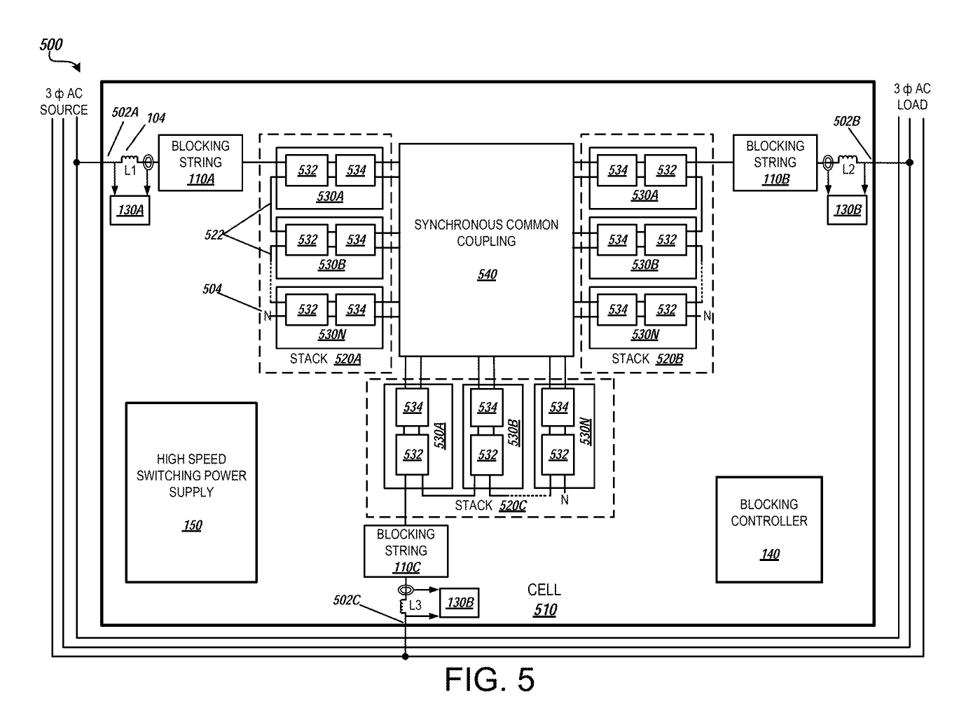

FIG. 5 is a block diagram illustrating a multi-level and multi-port cascaded power management system 500 with synchronous common coupling 540 and a 3-port cell 710 with blocking strings 110A-C, according to some aspects described herein. According to some aspects, the multi-level and multi-port cascaded power management system 500 may be implemented with one cell 510 connected to a three-phase AC power network to act as a VAR compensator or shunt regulator. In other aspects, this configuration may be utilized for line balancing, transformer impedance matching, or the like.

As shown in FIG. 5, the multi-level and multi-port cascaded power management system 500 may be implemented with a 3-port system comprising a cell 510, the cell 510 comprising of three cell ports 502A-C connected to each line of the three-phase AC power network. According to some aspects, the cell 510 may be implemented with a current regulating reactor 104, a voltage/current monitor 130, a blocking string 110, and a stack 520 for each line of the three-phase network. Further, the cell 510 may be implemented with a blocking controller 140 and high speed switching power supply 150 to control and activate each switch 210 within each blocker stage 120 contained within each blocking string 110A-C in the cell 510. Each stack 520 may comprise of multiple stages 530A-N, with each stage 530 connected in series. In the example aspect of the multi-level and multi-port cascaded power management system 500, the stacks 520A-C are coupled by a synchronous common coupling 540 using a single common flux core as the coupling path to exchange power directly between electrically isolated and non-isolated stages 530A-N of the stacks 520A-C.

Each stage 530 may comprise an input filter, a source/load bridge 532, a DC bus, and a flux bridge 534. In the example aspect, the cascaded stages 530 may have uniformly distributed capacitance to form a filter with the current regulating reactor 104. In the example aspect, the stages 530A-530N of each stack 520 may be connected in series, with the last stage 530N of each stack connected to a neutral electrical connection, or “neutral” 504. Each stack neutral 504 may be electrically independent or connected to one or more other stack neutrals 504 forming a group, and each neutral 504 or group of neutrals circuits within the power conversion system may be electrically floated and/or grounded by means of a solid conductor or one or more external network components such as a resistor, a inductor, or a capacitor.

In other aspects, the number of blocking strings 110, stages 530, stacks 520, and cells 510 used to form a power management system may depend on the network operating voltage and power. According to some aspects, as the voltage and current demands are increased for a particular power management apparatus, a plurality of blocking strings 110 may be connected in parallel to effectively provide a more robust blocking string which has increased the blocking and voltage-withstanding without increasing current and voltage ratings of each component within each blocking string 110 and each blocker stage 120.

It will be appreciated that the power management circuits, assemblies, and/or systems described herein may comprise any number of blocker stage, and each system or component may comprise any number of ports, and they may be combined in various ways for various configurations of a power management system, according to the aspects described herein.

Other aspects can comprise additional options or can omit certain options shown herein. One should note that conditional language, such as, among others, “can,” “could,” “might,” or “may,” unless specifically stated otherwise, or otherwise understood within the context as used, is generally intended to convey that certain aspects comprise, while other aspects do not comprise, certain features, elements and/or steps. Thus, such conditional language is not generally intended to imply that features, elements and/or steps are in any way required for one or more particular aspects or that one or more particular aspects necessarily comprise logic for deciding, with or without user input or prompting, whether these features, elements and/or steps are comprised or are to be performed in any particular aspect.

The description is provided as an enabling teaching of the present devices, systems, and/or methods in their best, currently known aspects. To this end, those skilled in the relevant art will recognize and appreciate that many changes can be made to the various aspects described herein, while still obtaining the beneficial results of the present disclosure. It will also be apparent that some of the desired benefits of the present disclosure can be obtained by selecting some of the features of the present disclosure without utilizing other features. Accordingly, those who work in the art will recognize that many modifications and adaptations to the present disclosure are possible and can even be desirable in certain circumstances and are a part of the present disclosure. Thus, the description is provided as illustrative of the principles of the present disclosure and not in limitation thereof.

As used throughout, the singular forms “a,” “an” and “the” comprise plural referents unless the context clearly dictates otherwise. Thus, for example, reference to a quantity of one of a particular element can comprise two or more such elements unless the context indicates otherwise. As used herein, the terms “optional” or “optionally” mean that the subsequently described event or circumstance may or may not occur, and that the description comprises instances where said event or circumstance occurs and instances where it does not.

It should be emphasized that the above-described examples are merely possible examples of implementations and set forth for a clear understanding of the present disclosure. Many variations and modifications can be made to the above-described examples without departing substantially from the spirit and principles of the present disclosure. Further, the scope of the present disclosure is intended to cover any and all appropriate combinations and sub-combinations of all elements, features, and aspects discussed above. All such appropriate modifications and variations are intended to be comprised within the scope of the present disclosure, and all possible claims to individual aspects or combinations of elements or steps are intended to be supported by the present disclosure.

1. A power management apparatus comprising:
a blocking string comprising a plurality of blocker stages connected in series, each blocker stage comprising at least one switch and at least one energy absorbing component;
a voltage/current monitor configured to monitor a power flow in the power management apparatus and to generate current feedback and voltage feedback; and
a central controller coupled to the voltage/current monitor, the central controller configured to detect a transient in the power flow in the power management apparatus based on the current feedback and the voltage feedback and to, upon detecting the transient, switch the energy absorbing components of the plurality of blocker stages into or out of the power flow by synchronously turning the at least one switch of each of the plurality of blocker stages on or off, wherein turning the at least one switch of each of the plurality of blocker stages on or off synchronously causes the plurality of blocker stages to effectively act as a single blocking component.

2. The power management apparatus of claim 1, further comprising an inverter connected in series with the blocking string.

3. The power management apparatus of claim 1, further comprising a high speed switching power supply coupled to the central controller and configured to supply power to each blocker stage.

4. The power management apparatus of claim 3, wherein the central controller synchronously switches the energy absorbing component of each of the plurality of blocker stages into or out of the power flow by controlling power delivered by the high speed switching power supply to each of the plurality of blocker stages.

5. The power management apparatus of claim 1, wherein each of the plurality of blocker stages further comprises control circuitry coupled to the central controller, the control circuitry configured to synchronously turn on or off the at least one switch within each respective blocker stage based on a control signal from the central controller.

6. The power management apparatus of claim 1, wherein the energy absorbing component of each of the plurality of blocker stages comprises an arrestor.

7. The power management apparatus of claim 1, wherein the energy absorbing component of each of the plurality of blocker stages comprises a resistor.

8. The power management apparatus of claim 1, wherein the at least one switch of each of the plurality of blocker stages is configured to be switched on and off at high speed.

9. The power management apparatus of claim 1, wherein the plurality of blocker stages are configured for bi-directional alternating current and direct current (“AC/DC”) power flow.

10. The power management apparatus of claim 1, wherein each of the plurality of blocker stages further comprises at least one discharge component coupled in parallel to the at least one switch.

11. (canceled)

12. The power management apparatus of claim 1, wherein the energy absorbing component of each of the plurality of blocker components is coupled in parallel to the at least one switch.

13. A power management system comprising:
a plurality of ports;
a blocking string electrically connected to each of the plurality of ports, each blocking string comprising a plurality of blocker stages connected in series, each blocker stage comprising at least one switch and at least one energy absorbing component, each blocker stage configured to switch the at least one energy absorbing component into and out of a power flow from a respective one of the plurality of ports based on a control signal, wherein the control signal synchronously turns the at least one switch of each of the plurality of blocker stages on or off such that the blocking strings effectively act as a single blocking component; and
a plurality of inverters, each inverter connected in series with at least one blocking string.

14. The power management system of claim 13, wherein the control signal comprises power being supplied to each of the plurality of blocker stages from a single high speed switching power supply controlled by a central controller based on predetermined criteria.

15. The power management system of claim 13, wherein each inverter of the plurality of inverters comprises an electrically isolated stack connected together by a synchronous common coupling.

16. The power management system of claim 13, further comprising a reactor connected between each of the plurality of ports and a corresponding blocking string.

17. A method for controlling power flow in a power management system, the method comprising:
sensing, by a voltage/current monitor, current feedback and voltage feedback;
determining, by a central controller, if a transient event has occurred based on the current feedback and the voltage feedback compared to predetermined criteria; and
upon determining the transient event has occurred, synchronously activating a plurality of blocker stages connected in series, each blocker stage comprising at least one high speed switch and at least one energy absorbing component;
wherein activating a blocker stage comprises switching the at least one energy absorbing component into the power flow utilizing the respective at least one high speed switch;
wherein synchronously activating the plurality of blocker stages effectively acts as a single blocking component.

18. The method of claim 17, wherein the central controller is coupled to a high speed switching power supply and configured to synchronously switch the energy absorbing component of each of the plurality of blocker stages into or out of the power flow by controlling power delivered by the high speed switching power supply to each of the plurality of blocker stages.

19. The method of claim 17, further comprising, upon determining the transient event has ended, switching the energy absorbing component out of the power flow utilizing the high speed switch.

20. The method of claim 17, wherein the predetermined criteria comprises a preset time interval for at least one of a voltage magnitude threshold, a rate of change of current slope threshold, and a current magnitude threshold.
